(19) United States
(12) Patent Application Publication
(10) Pub. No.: US 2026/0250882 A1
(43) Pub. Date: Aug. 27, 2026

(54) GALLIUM NITRIDE SINGLE CRYSTAL SUBSTRATE

(71) Applicant: SUMITOMO CHEMICAL COMPANY, LIMITED, Tokyo (JP)

(72) Inventors: Seiji SARAYAMA, Ibaraki (JP); Toshio KITAMURA, Ibaraki (JP)

(21) Appl. No.: 19/412,962

(22) Filed: Dec. 9, 2025

(30) Foreign Application Priority Data
Feb. 26, 2025 (JP) 2025-028514

(51) Int. Cl. C30B 29/40; C30B 25/02; C30B 33/08

(52) U.S. Cl. CPC C30B 29/406; C30B 25/02; C30B 33/08

(57) ABSTRACT

A gallium nitride single crystal substrate, that is a gallium nitride single crystal substrate having a diameter of 50 mm or more and two main surfaces facing in opposite directions, wherein when light having a wavelength of 532 nm is incident perpendicularly to one of the main surfaces, light diffusion transmittance Rd, which is a value obtained by dividing an intensity of diffused transmitted light by an intensity of total transmitted light, satisfies Rd<0.000791.

### BACKGROUND

### Technical Field

The present disclosure relates to a gallium nitride single crystal substrate.

### Description of Related Art

When a semiconductor single crystal is processed into a substrate, its surface contains a surface layer (hereinafter referred to as a processing-affected layer) that has regions of single crystal that are disordered, crystal distortions and scratches, such as a polycrystalline layer or an amorphous layer, introduced during slicing or grinding/polishing.

For example, Patent Document 1 discloses a method for evaluating a processing-affected layer of a semiconductor single crystal substrate, in which laser light is incident on the surface of the semiconductor single crystal substrate and the processing-affected layer of the semiconductor single crystal substrate is evaluated based on the intensity of the reflected and scattered light scattered in the inside of the semiconductor single crystal substrate.

Further, Patent Document 2 discloses that the CL (cathodoluminescence) method is used to evaluate the processing-affected layer, and that the processing-affected layer is removed by performing CMP (Chemical Mechanical Polishing) after grinding using a high-grit grinding wheel. Grinding using the high-grit grinding wheel as described in Patent Document 2 will hereinafter be referred to as precision grinding.

### CITATION LIST

### Patent Document

[Patent Document 1] Japanese Patent No. 7344491
[Patent Document 2] Japanese Patent Application Publication No. 2023-032894

### SUMMARY OF THE INVENTION

An object of the present disclosure is to provide a gallium nitride single crystal substrate without a processing-affected layer.

According to one aspect of the present disclosure, there is provided a gallium nitride single crystal substrate,
that is a gallium nitride single crystal substrate having a diameter of 50 mm or more and two main surfaces facing in opposite directions,
wherein when light having a wavelength of 532 nm is incident perpendicularly to one of the main surfaces, light diffusion transmittance Rd, which is a value obtained by dividing an intensity of diffused transmitted light by an intensity of total transmitted light, satisfies Rd<0.000791.

According to another aspect of the present disclosure, there is provided a gallium nitride single crystal substrate,
that is a gallium nitride single crystal substrate having a diameter of 50 mm or more and two main surfaces facing in opposite directions,
wherein when light is incident perpendicularly to one of the main surfaces using a spectrophotometer, there is at least one wavelength λ of incident light in a range of 390 nm or more and 600 nm or less, at which light diffusion transmittance Rd, which is a value obtained by dividing an intensity of diffused transmitted light by an intensity of total transmitted light, satisfies the following formula (1):

$$Rd < a \times {b}^{2} \div ( c \times {( λ - {λ}_{0} )}^{2} + {b}^{2} ) + d \qquad ( 1 )$$

[In formula (1), a=10, b=1.2, c=2.5, d=0.00065, λ is a wavelength (nm) of the incident light, and λ₀=330.]

### Advantageous Effects of Invention

According to the present disclosure, there is provided a gallium nitride single crystal substrate without a processing-affected layer.

### BRIEF DESCRIPTION OF THE DRAWINGS

FIG. 1 is a flow chart showing an example of a method for manufacturing a nitride semiconductor substrate 100 according to a first embodiment of the present disclosure.

FIG. 2 is a schematic view for explaining a CMP processing step S102 according to the first embodiment of the present disclosure.

FIG. 3 is a schematic view for explaining a processing-affected layer evaluation step S103 according to the first embodiment of the present disclosure.

FIG. 4 is a schematic view of a spectrophotometer having an integrating sphere (with a reflector).

FIG. 5 is a schematic view of a spectrophotometer having an integrating sphere (without a reflector).

FIG. 6 is a schematic view for explaining a CMP processing step S102 according to another embodiment of the present disclosure.

FIG. 7 is a cathodoluminescence (CL) image of a main surface (before CMP processing) of Sample 1 according to an example of the present disclosure.

FIG. 8 is a CL image of the main surface (after CMP processing) of Sample 1 according to the example of the present disclosure.

FIG. 9 is a CL image of the main surface (after CMP processing) of Sample 2 according to the example of the present disclosure.

FIG. 10 is a CL image of the main surface (after CMP processing) of Sample 3 according to the example of the present disclosure.

FIG. 11 is a CL image of the main surface (after CMP processing) of Sample 4 according to the example of the present disclosure.

FIG. 12 is a view schematically showing a CL image (left side of the page) and a SEM backscattered electron image (right side of the page) of the main surface (before CMP processing) of Sample 1 according to the example of the present disclosure.

FIG. 13 is a view schematically showing a CL image (left side of the page) and a SEM backscattered electron image (right side of the page) of the main surface (after CMP processing) of Sample 1 according to the example of the present disclosure.

FIG. 14 is a graph showing the results of calculating the light diffusion transmittance Rd for Samples 1 to 4 according to the example of the present disclosure using a spectrophotometer.

FIG. 15 is a graph in which a vertical axis of FIG. 14 is adjusted.

FIG. 16 is a schematic view for explaining a configuration of a conventional CMP processing.

### DETAILED DESCRIPTION OF THE INVENTION

### <Findings Obtained by the Inventors>

First, the findings obtained by the inventors will be described.

When laser light is incident on a gallium nitride single crystal substrate (hereinafter also referred to as a GaN substrate) from an oblique direction relative to a substrate main surface as described in patent document 1, thereby evaluating a processing-affected layer based on the intensity of the reflected and scattered light, it was found that the processing-affected layer could not be evaluated correctly due to a strong influence of particles on the substrate surface with diameters on the order of submicron to m, and surface irregularities.

Further, although patent document 2 makes it possible to reduce the processing-affected layer by precision grinding and CMP, it does not disclose how to reduce the processing-affected layer to zero, that is, how to completely remove the processing-affected layer. When CMP is performed to a GaN substrate to remove the processing-affected layer, a new processing-affected layer is generated by the CMP, making it difficult to completely remove the processing-affected layer. Particularly, when polishing the c-plane of the GaN substrate, there is a problem in that a processing-affected layer is easily introduced.

The inventors have conducted extensive research into the above-described problem and have found that the processing-affected layer of the GaN substrate can be completely removed by reducing a contact area between a CMP pad and the GaN substrate.

Typically, in the CMP processing, an entire surface of the crystal to be processed (main surface) is brought into contact with a CMP pad attached to a flat surface plate, thus allowing the CMP processing to proceed by rotating both the surface plate and the crystal. That is, the contact area between the CMP pad and the substrate is equal to the area of the main surface. At this time, it was found that if there are multiple dislocations (threading dislocations) that penetrate the main surface of the crystal, new crystal defects will occur between the threading dislocations.

FIG. 16 is a schematic view for explaining the configuration of a conventional CMP processing. As shown in FIG. 16, in the conventional CMP processing, the main surface of a workpiece 10 and the upper surface of a surface plate 20 are parallel to each other, and therefore an entire main surface is in contact with a CMP pad 21. With this configuration, when CMP processing is performed to the main surface of GaN crystal in which the threading dislocation density is a predetermined density or more (for example, a threading dislocation density of approximately 10⁶ cm⁻²), a new crystal defect is generated between the threading dislocations.

In contrast, by narrowing the contact area between the CMP pad and the GaN substrate in accordance with the crystal threading dislocation density (for example, by making it smaller than the area of the main surface of the GaN substrate), CMP processing can be performed without causing any crystal defect between the threading dislocations. This processing method realizes a GaN substrate without a processing-affected layer.

### DETAILS OF THE EMBODIMENT OF THE PRESENT DISCLOSURE

Next, one embodiment of the present disclosure will be described below with reference to the drawings. The present disclosure is not limited to these examples, but is defined by the scope of the claims, and is intended to include all modifications within the meaning and scope equivalent to the claims.

### First Embodiment of the Present Disclosure

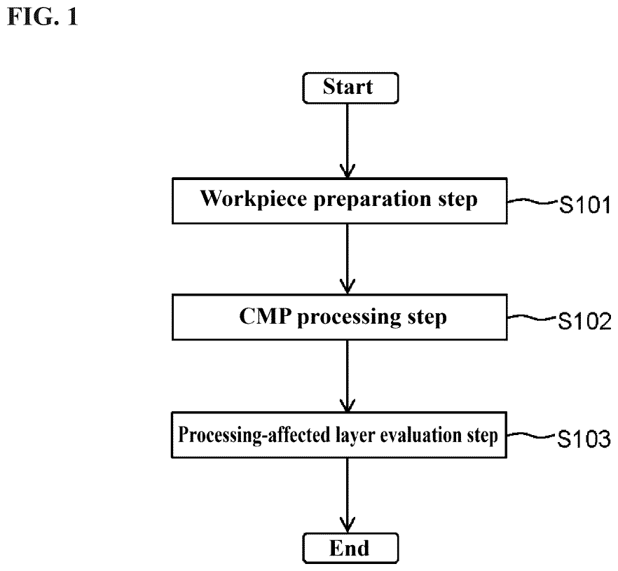

First, a method for manufacturing a nitride semiconductor substrate 100 (also referred to as a GaN substrate 100) of this embodiment will be described. FIG. 1 is a flow chart showing an example of a method for manufacturing a nitride semiconductor substrate 100 according to this embodiment. As shown in FIG. 1, the method for manufacturing the nitride semiconductor substrate 100 of this embodiment includes, for example, a workpiece preparation step S101, a CMP processing step S102, and a processing-affected layer evaluation step S103.

### (Workpiece Preparation Step S101)

The workpiece preparation step S101 is a step of preparing a workpiece 10 composed of a nitride semiconductor such as gallium nitride. This embodiment shows a case in which the workpiece 10 is a gallium nitride single crystal intermediate for manufacturing a gallium nitride single crystal substrate (GaN substrate). Specifically, for example, gallium nitride is epitaxially grown by HVPE (hydride vapor phase epitaxy), etc., to obtain bulk crystal of gallium nitride, and then the workpiece 10 can be prepared by performing appropriate slicing, grinding, polishing, etc. The diameter of the workpiece 10 is, for example, 2 inches or more and 8 inches or less (50 mm or more and 200 mm or less). In this embodiment, the main surface of the workpiece 10 to be CMP processed is, for example, a c-plane, where the c-plane is {0001} as an index plane, and the c-axis is [0001].

The main surface of the workpiece 10 is flattened by mechanical polishing, precision grinding, etc., and surface roughness Ra of the main surface is, for example, 10 nm or less. However, the processing-affected layer is introduced into the main surface of the workpiece 10 during slicing, grinding, and polishing, and in order to manufacture a high-performance device, the processing-affected layer must be completely removed.

### (CMP Processing Step S102)

The CMP processing step S102 is, for example, a step of performing chemical mechanical polishing (CMP) to the main surface of the workpiece 10. This step completely removes the processing-affected layer introduced into the main surface of the workpiece 10.

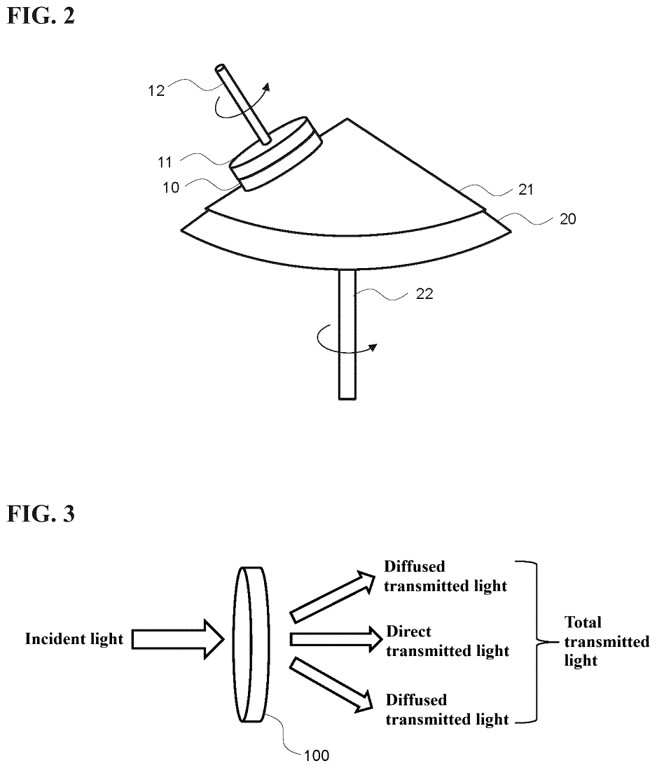

FIG. 2 is a schematic view for explaining the CMP processing step S102 of this embodiment. As shown in FIG. 2, in this step, for example, the workpiece 10 is rotated with the center of the main surface of the workpiece 10 as a rotation axis, and while rotating, brought into contact with a chemical mechanical polishing pad (CMP pad 21) attached to a surface plate 20 of a chemical mechanical polishing apparatus (CMP apparatus). The material of the CMP pad 21 and the chemical mechanical polishing slurry used here may be a known material. The “slurry” used here refers to a liquid called a lubricant in which abrasive grains are dispersed. When the workpiece 10, which is a GaN crystal, is brought into contact with the CMP pad 21 interposing the slurry therebetween, the lubricant oxidizes a GaN crystal surface through a chemical reaction to form gallium oxide, which is then mechanically polished away by the abrasive grains. In this case, by selecting a material as the abrasive grains that is harder than gallium oxide but softer than GaN, the only substance that is mechanically polished away is gallium oxide. Therefore, the processing-affected layer can be removed while preventing the GaN crystal itself from being polished away. That is, it is preferable to select abrasive grains satisfying a hardness relationship as follows: gallium oxide<abrasive grains<GaN crystals, and as a specific abrasive grain material, colloidal silica, etc., can be used.

As shown in FIG. 2, in the CMP processing step S102 of this embodiment, for example, a conical surface plate 20 is used, and the CMP pad 21 also has a conical shape following the surface plate 20. A work holder 11 that supports the workpiece 10 is, for example, in the shape of a flat disk, and the surface of the work holder 11 is in contact with the surface opposite to the main surface of the workpiece 10, and the main surface and the surface of the work holder 11 are approximately parallel. A work rotation axis 12 is located approximately at the center of the surface of the work holder 11 opposite to the surface to which the workpiece 10 is attached, and this rotation axis is approximately parallel to a direction normal to the surface of the work holder 11, and also a direction normal to the conical surface to which the CMP pad 21 is attached. A rotating shaft 22 for rotating the surface plate is located approximately at the center of the lower surface of the conical surface plate 20. With this configuration, the area of contact between the main surface of the workpiece 10 and the CMP pad 21 (contact area) is not equal to an entire surface area of the main surface of the workpiece 10, but is smaller than the area of the main surface. By rotating the workpiece 10, the entire main surface can be subjected to CMP processing. Performing the CMP processing in this manner suppresses the generation of a new processing-affected layer (crystal defect) during the CMP processing. Thus, the processing-affected layer can be completely removed.

The contact area S_{c} between the main surface of the workpiece 10 and the CMP pad 21 can be adjusted by the shape, size, and material of the CMP pad 21, the pressure applied to press the workpiece 10 against the CMP pad 21, and other factors. In the CMP processing step S102, it is preferable to control the contact area S_{c} in accordance with the threading dislocation density (TDD) in the main surface of the workpiece 10. The higher the threading dislocation density (TDD), the more likely the new crystal defect is to occur between the threading dislocations. Therefore, it is preferable to control the contact area S_{c} to be small when performing the CMP processing. This further suppresses the generation of the new processing-affected layer (crystal defect) during the CMP processing.

Specifically, the contact area S_{c} between the main surface of the workpiece 10 and the CMP pad 21 is preferably set as follows: 10% or less of the main surface area S₀ when the threading dislocation density (TDD) in the main surface is 1×10⁷ cm⁻² or more; greater than 10% and 30% or less of S₀ when the TDD is 1×10⁶ cm⁻² or more and less than 1×10⁷ cm⁻²; greater than 30% and 50% or less of S₀ when the TDD is 1×10⁵ cm⁻² or more and less than 1×10⁶ cm⁻²; and greater than 50% and less than 100% of S₀ when the TDD is less than 1×10⁵ cm⁻². In this way, by controlling the contact area Sc in accordance with the threading dislocation density TDD in the main surface, the processing-affected layer can be uniformly removed over the surface and improve the in-plane uniformity of the GaN substrate 100.

The CMP processing step S102 allows for the complete removal of the processing-affected layer on the main surface of the workpiece 10 and improves the flatness of the main surface. Specifically, after performing the CMP processing step S102, the main surface of the workpiece 10 (GaN substrate 100) becomes a mirror-polished surface with a surface roughness Ra of 1 nm or less.

### (Processing-Affected Layer Evaluation Step S103)

The processing-affected layer evaluation step S103 is, for example, a step of evaluating the processing-affected layer on the main surface of the workpiece 10 (GaN substrate 100). That is, this step can be rephrased as a step of confirming whether the processing-affected layer of the GaN substrate 100 has been completely removed.

Paragraph 0002 of patent document 1 defines the processing-affected layer as “a surface layer containing crystal distortion, scratches, and other defects introduced during slicing, grinding, and polishing.” Among these, the processing-affected layer that poses a particular problem in the GaN crystal is a portion other than a region where the crystal distortion is within an elastic deformation range of a crystal lattice; it is a region of disorder in the single-crystal structure introduced by the crystal processing step, that is, a plastic deformation region of the crystal lattice. Further, the surface irregularities and the processing-affected layer of the substrate are different phenomena. Even if there are stresses (strains) inherent in the inside of crystal or irregularities as a geometric shape, as long as the plastic deformation region of the crystal lattice introduced during the crystal processing step is removed, there will be no problem in subsequent steps. However, the laser light reflection and scattering evaluation method described in patent document 1 makes it difficult to separate the surface irregularities and the processing-affected layer of the substrate.

Further, patent document 2 discloses that performing CMP after precision grinding using a high-grit grinding wheel removes the processing-affected layer, and that appropriately selecting the abrasive grain size of the grinding wheel during precision grinding can shorten the processing time including the CMP processing. Here, cathodoluminescence (CL) is used to evaluate the processing-affected layer resulting from processing, and this processing-affected layer is considered to consist of a main processing-affected layer and subsurface damage. Although it is not described how the main processing-affected layer is observed under CL (cathodoluminescence), it is explained that the subsurface damage can be observed as dark lines. This patent document 2 describes that processing time can be shortened by using grinding with an appropriate abrasive grain size and CMP, as described above, but it does not describe complete removal of subsurface damages. That is, it can be said that the processing-affected layer has not been completely removed. Further, paragraph 0042 of this patent document 2 describes that it is difficult to ensure that there are no subsurface damages over a wide area over the entire substrate in the case of CL. Further, patent document 2 describes that the subsurface damages constituting the processing-affected layer can be detected using CL (cathodoluminescence), but in reality, it is sometimes not possible to detect them. CL utilizes the property that GaN crystal emits light when irradiated with electron beams, and when linear or planar crystal defects such as dislocations and stacking faults (including crystal defects in the processing-affected layer introduced during the crystal processing step) are present, those regions become non-light-emitting regions and are observed as dark lines or dark areas. However, when the processing-affected layer is extremely fine or is present in an extremely shallow region of a crystal surface compared to a penetration depth of electron beams, light emission from the crystal matrix surrounding the processing-affected layer or in areas deeper than the processing-affected layer can often mask dark lines or dark areas, making them undetectable due to a lack of contrast. As a result, it frequently happens that nothing is found during CL surface observation, even though the processing-affected layer is present. Then, it often happens that even when there is a processing-affected layer, nothing is found when observing the CL surface. When observing by cathodoluminescence (CL), the electron penetration depth into the GaN crystal is approximately 150, 470, and 900 nm at electron acceleration voltages of 5, 10, and 15 kV, respectively. As observed in the examples below, the processing-affected layer that is equivalent to or deeper than the electron penetration depth can be detected by surface observation by CL (cathodoluminescence), but observing the processing-affected layer in a region significantly shallower than that depth is difficult for the reason described above. Therefore, even with an accelerating voltage of 5 kV, which results in a shallowest electron penetration depth, it is difficult to observe a non-light-emitting component (such as a processing-affected layer) at a depth shallower than 150 nm from the surface. Further, when the accelerating voltage is too low (for example, less than 5 kV), the resolution decreases, making CL observation itself difficult.

Another problem is that when CL observation is performed to evaluate the processing-affected layer after CMP, electron beam irradiation mainly causes carbon-based deposits to form on the crystal surface, requiring a cleaning processing to remove them. That is, while patent document 2 describes cleaning after CMP, subsequent CL observation reveals that further cleaning is required to remove the carbon-based deposits.

Paragraphs 0030 to 0032 of patent document 1 disclose that particles adhering to the substrate surface can be removed by various cleaning methods. However, these cleaning procedures do not necessarily guarantee the complete removal of particles adhering to the GaN crystal surface that were generated during the GaN crystal processing, or carbon-based deposits that were generated during CL observation. Particularly, in the cleaning method using ammonia water and hydrogen peroxide solution disclosed in paragraph 0032 of patent document 1, the opposite side of the c-plane, which is commonly used as a main surface, namely a nitrogen-polar surface (N-plane) on the back side, is etched, resulting in a collapse of a desired shape. This poses a problem that requires re-polishing of the back surface.

An object of the present disclosure is to provide a gallium nitride single crystal substrate without the processing-affected layer. The object is to establish a technique that allows for the evaluation of the presence or absence of the processing-affected layer over a wide area with high resolution in a depth direction, which has been difficult until now, while simultaneously achieving the complete removal of the processing-affected layer.

As a result of intensive research by the inventors, it is found that by using a spectrophotometer, light (e.g., white light) is incident from a direction approximately normal to the main surface of the GaN substrate, and a light diffusion transmittance Rd, which is a value obtained by dividing the intensity of diffused transmitted light by the intensity of total transmitted light, allows for accurate evaluation of the processing-affected layer of the GaN substrate.

As described above, in the case of reflection and scattering evaluation using laser light, there is a problem in that particles adhering to the surface and surface irregularities are also acquired as data. In contrast, the measurement using the technique of the present disclosure, which includes analyzing the spectrum of transmitted light with white light, showed that above problem was small, indicating that it is suitable for evaluating the processing-affected layer. Further, it was found that the processing-affected layer can also be evaluated by irradiating it with light of a specific wavelength, in addition to white light, and calculating the light diffusion transmittance Rd. Also, the evaluation of the processing-affected layer using the technique of the present disclosure has an advantage that it eliminates the need to clean the gallium nitride single crystal substrate after evaluation, thus allowing a clean surface to be maintained.

FIG. 3 is a schematic view showing the processing-affected layer evaluation step S103. As shown in FIG. 3, in the processing-affected layer evaluation step S103 of this embodiment, a spectrophotometer is used to irradiate light perpendicularly to the main surface of the GaN substrate 100. A light irradiation area is preferably, for example, 10 mm or more in diameter. The light that passes through the GaN substrate 100 without diffusing is defined as a direct transmitted light, and the light that is diffused and then transmitted through the GaN substrate 100 is defined as a diffused transmitted light. The light diffusion transmittance Rd is calculated by dividing the intensity of the diffused transmitted light by the intensity of the total transmitted light (direct transmitted light+diffused transmitted light). That is, when there is a crystal defect in the inside of the crystal that is of a size that causes scattering at the wavelength of the incident light, then the light diffusion transmittance Rd measured using this spectrophotometer will be higher. In this specification, “perpendicular to the main surface of the GaN substrate 100” includes not only being perfectly perpendicular to the main surface, but also being slightly deviated from a perpendicular direction by a small angle (e.g., 5 degrees or less).

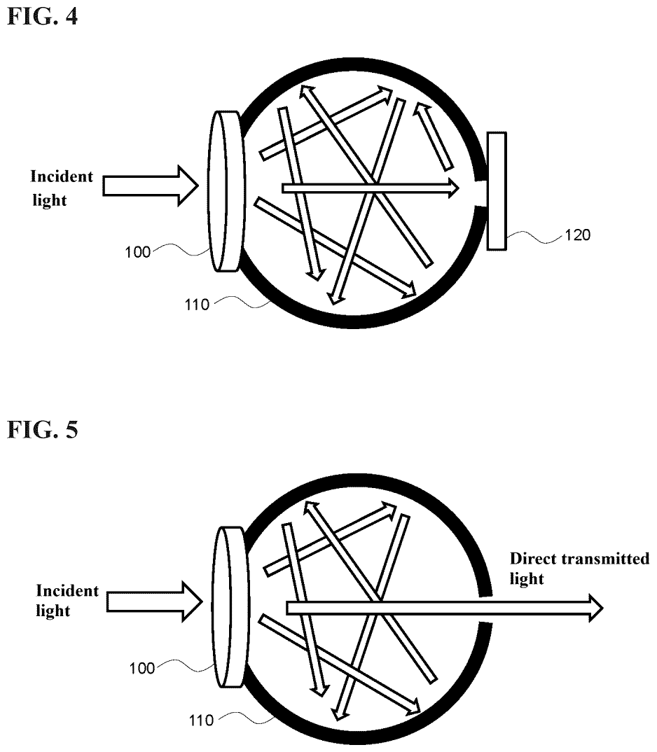

The method for measuring the light diffusion transmittance Rd will be explained in more detail. FIGS. 4 and 5 are schematic views of a spectrophotometer having an integrating sphere. As shown in FIG. 4, when the exit of the integrating sphere 110 is blocked by a reflector 120, the total transmitted light that passes through the GaN substrate 100 is detected after multiple reflections within the integrating sphere 110. Therefore, the intensity of the total transmitted light can be measured. On the other hand, as shown in FIG. 5, in the absence of the reflector 120, only direct transmitted light is emitted from the integrating sphere 110. Therefore, the intensity of the diffused transmitted light can be measured. Then, the value obtained by dividing the intensity of the diffused transmitted light by the intensity of the total transmitted light is the light diffusion transmittance Rd.

The more the processing-affected layer is present, the greater the proportion of the diffused transmitted light. Therefore, the substrate having a low light diffusion transmittance Rd can be said to have a less processing-affected layer. As a result of intensive research by the inventors, it was found that when the light diffusion transmittance Rd satisfies the following formula (1), it can be considered that the processing-affected layer on the main surface had been completely removed.

$$Rd < a \times {b}^{2} \div ( c \times {( λ - {λ}_{0} )}^{2} + {b}^{2} ) + d \qquad ( 1 )$$

In the formula (1), a=10, b=1.2, c=2.5, d=0.00065, λ is the wavelength (nm) of the incident light, and λ₀=330.

That is, when there are scatterers (crystal defects or inclusions) in the inside of the crystal, that are about 1/10 of the wavelength λ of the incident light, Rd will increase, and the size of these scatterers in the processing-affected layer can be said to be about several tens to 100 nm. In other words, when the formula (1) is satisfied, there can be no scatterers larger than this size. In fact, when a diode device was fabricated by epitaxial growth on this crystal, a good device with small leakage current was obtained. On the other hand, when a similar fabrication was performed to a crystal that did not satisfy the formula (1), the resulting device had a large leakage current.

In the processing-affected layer evaluation step S103, for example, it is sufficient to confirm that there is at least one wavelength λ of the incident light in the range of 390 nm or more and 600 nm or less at which the light diffusion transmittance Rd satisfies the above formula (1). Further, when the wavelength λ (nm) of the incident light is an integer value, it is preferable that the light diffusion transmittance Rd satisfies the above formula (1) at a wavelength value of λ equal to or greater than half of the range of 390 nm or more and 600 nm or less. Further, it is more preferable that the light diffusion transmittance Rd satisfies the above formula (1) at the wavelength λ of the incident light over an entire range of 390 nm or more and 600 nm or less. If the light diffusion transmittance Rd does not satisfy the above formula (1), the CMP processing step S102 is performed again under an appropriate condition until the processing-affected layer is completely removed.

The remaining/removed state of the processing-affected layer on the main surface can also be confirmed by, for example, CL-observing the cross section of the GaN substrate 100. The CL-observation of the cross section of the GaN substrate 100 that has been cleaved so as not to damage the main surface side reveals that when there is a processing-affected layer, dark areas are observed in a layered manner near the main surface. That is, when CL observation of the cross section of the GaN substrate 100 reveals that no dark areas are present, it can be said that the processing-affected layer has been removed. The CL observation of the cross section does not involve the problem of the penetration depth of electrons described above, and the degree of removal of the processing-affected layer can be evaluated based on whether or not the dark areas exist in a layered manner near the surface (main surface). However, the cross-sectional CL observation involves a problem that this is a destructive test, and further, the size of the area that can be observed is limited by the magnification of the scanning electron microscope (SEM), making it difficult to evaluate the entire surface of the GaN crystal in a short period of time. Further, when the processing-affected layer is evaluated by CL observation, there is a disadvantage in that cleaning is required to remove carbonaceous deposits after the evaluation. In contrast, in the evaluation of the processing-affected layer using diffused light transmittance according to the present disclosure, there is a wide evaluation area, and the non-destructive evaluation can be performed over the entire substrate surface, and there is no problem of resolution in the depth direction or surface contamination.

The evaluation of the processing-affected layer may be performed at multiple arbitrary points on the main surface. When the deviation ((maximum value−minimum value)÷average value) of the light diffusion transmittance Rd measured at multiple arbitrary points on the main surface is 5% or less, it can be said that the processing-affected layer has been removed uniformly within the surface. The deviation may be calculated using the average value of the light diffusion transmittance Rd at the wavelength λ of the incident light in the range of 390 nm or more and 600 nm or less, or may be calculated using the light diffusion transmittance Rd corresponding to arbitrary λ in the range of 390 nm or more and 600 nm or less.

Through the above steps, the GaN substrate 100 can be manufactured from which the processing-affected layer has been completely removed. The GaN substrate 100 manufactured by the manufacturing method of this embodiment is particularly suitable for manufacturing a high-performance device.

### (2) Nitride Semiconductor Substrate 100

Next, the nitride semiconductor substrate 100 (GaN substrate 100) of this embodiment will be described. The GaN substrate 100 is, for example, a gallium nitride single crystal substrate having a diameter of 50 mm or more and two main surfaces facing in opposite directions. The two main surfaces of the GaN substrate 100 are mirror-polished to a surface roughness Ra of 1 nm or less in the CMP processing step S102.

The GaN substrate 100 is in a state where the processing-affected layer on the main surface has been completely removed in the CMP processing step S102. To confirm that the processing-affected layer has been completely removed, it is sufficient to confirm in the processing-affected layer evaluation step S103 that the light diffusion transmittance Rd satisfies the above-described condition. Further, the light diffusion transmittance Rd satisfying the above-described condition also means that no inclusions are contained inside of the crystal. That is, the inside of the crystal of the GaN substrate 100 does not contain any inclusion that can be detected by transmission microscope observation using at least one of ultraviolet light, visible light, and infrared light having a wavelength longer than a band edge wavelength of the crystal. When confirming the absence of inclusions by observation with a transmission microscope, it is preferable to check with a field of view of φ10 mm or more.

Further, it may be confirmed by the CL observation of the cross section, that the processing-affected layer has been completely removed. For example, it may be confirmed by the CL observation of the cross section obtained by cleaving the GaN substrate 100, that no dark areas corresponding to the processing-affected layer are observed in the region up to 150 nm from the main surface.

### Other Embodiments of the Present Disclosure

Although the embodiments of the present disclosure have been specifically described above, the present disclosure is not limited to the above-described embodiments and can be modified in various ways without departing from the spirit of the present invention.

For example, the above embodiment shows a case where the light diffusion transmittance Rd is measured by varying the wavelength λ of the incident light in the range of 390 nm or more and 600 nm or less in the processing-affected layer evaluation step S103. However, in the processing-affected layer evaluation step S103, the light diffusion transmittance Rd may be measured at a specific wavelength, and the processing-affected layer may be evaluated based on whether or not the above formula (1) is satisfied. Specifically, when light having a wavelength of 532 nm is incident perpendicularly to the main surface of the GaN substrate 100, and the light diffusion transmittance Rd satisfies Rd<0.000791, it may be considered that the processing-affected layer on the main surface has been completely removed. When this method is used, it becomes easier to evaluate the processing-affected layer.

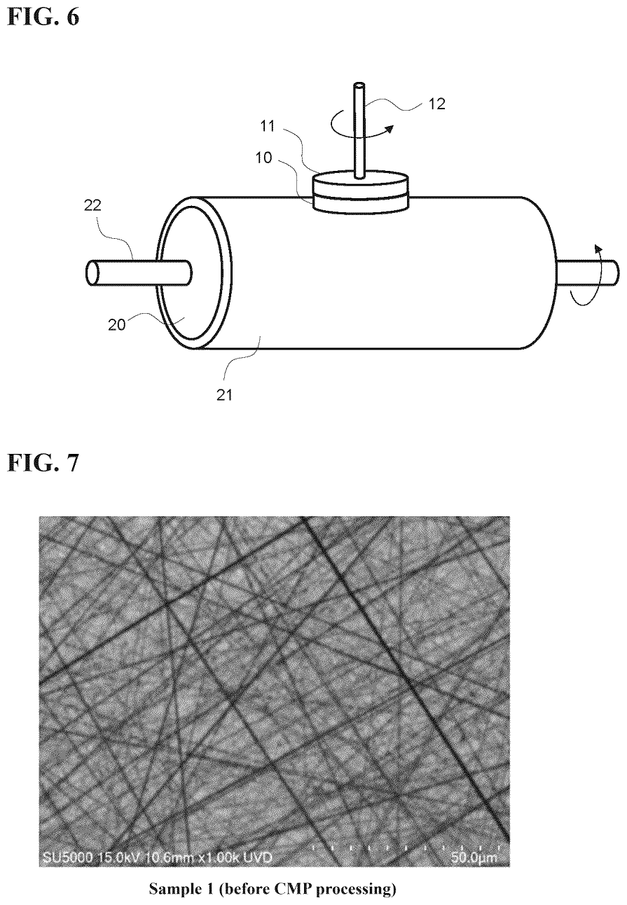

FIG. 6 is a schematic view for explaining the CMP processing step S102 according to another embodiment of the present disclosure. As shown in FIG. 6, in the CMP processing step S102, the CMP pad 21 may be attached to the surface (side surface) of the cylinder (or column) of the surface plate 20 having a cylindrical (or columnar) shape. The work holder 11 is a flat disk-shaped member similar to that of the first embodiment, and the work rotation axis 12 is approximately parallel to the normal direction of the side surface of the cylinder (column) to which the CMP pad 21 is attached. With this configuration, as in the first embodiment, the area (contact area) when the main surface of the workpiece 10 is brought into contact with the CMP pad 21 can be smaller than the area of the main surface. This prevents the generation of a new processing-affected layer (crystal defect) during the CMP processing, and completely removes the processing-affected layer.

The above embodiment shows a case where the CMP processing step S102 is performed on both main surfaces (the Ga face of the +c-plane and the N-face of the −c-plane) of the workpiece 10. However, The N-face of the GaN crystal is susceptible to chemical etching, and so the processing-affected layer can be removed even when polishing is performed using a conventionally known method (for example, CMP processing using an alkaline slurry in a conventional CMP apparatus as shown in FIG. 16). Therefore, the GaN substrate 100 according to the present disclosure includes a substrate in which, even if the N-face has an uneven, matte finish, it is mirror-polished by a conventionally known method so that the surface roughness Ra is 1 nm or less, and as a result, in the processing-affected layer evaluation step S103, the light diffusion transmittance Rd satisfies the above-described condition.

The processing-affected layer evaluation step S103 described in the above embodiment can also be used as the step of a method for evaluating a GaN substrate, in which the presence or absence of the processing-affected layer is evaluated.

### EXAMPLES

Next, examples of the present disclosure will be described. These examples are merely examples of the present disclosure, and the present disclosure is not limited to these examples.

### Example 1

First, four workpieces composed of gallium nitride single crystal having a diameter of 50 mm and a threading dislocation density of 3×10⁶ cm⁻² in the c-plane that is a main surface were prepared as Samples 1 to 4. Samples 1 to 4 were subjected to precision grinding so that the surface roughness Ra of the main surface was 10 nm or less. FIG. 7 shows a cathodoluminescence (CL) image of the main surface of Sample 1 (before CMP processing). CL observation was performed using a scanning electron microscope (SU5000) manufactured by Hitachi High-Tech Corporation. As shown in FIG. 7, dark areas and dark lines were present in the main surface of the workpiece, and it was confirmed that a processing-affected layer had been introduced.

Next, for Samples 1 to 6, CMP processing was performed to the main surfaces of both of them until the surface roughness Ra was 1 nm or less. For Sample 1, CMP processing was performed using the configuration shown in FIG. 2, which was explained as the first embodiment, and the contact area between the main surface of the workpiece and the CMP pad was controlled to be 20% of the area of the main surface. For samples 2 to 4, CMP processing was performed using the configuration shown in FIG. 16, which was explained as a conventional example, that is, using the configuration in which the entire main surface of the workpiece was in contact with the CMP pad.

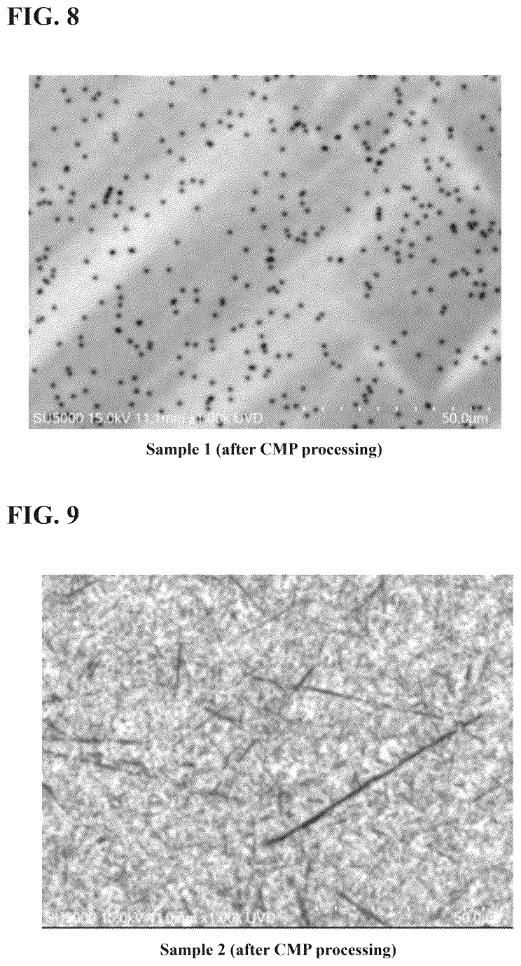

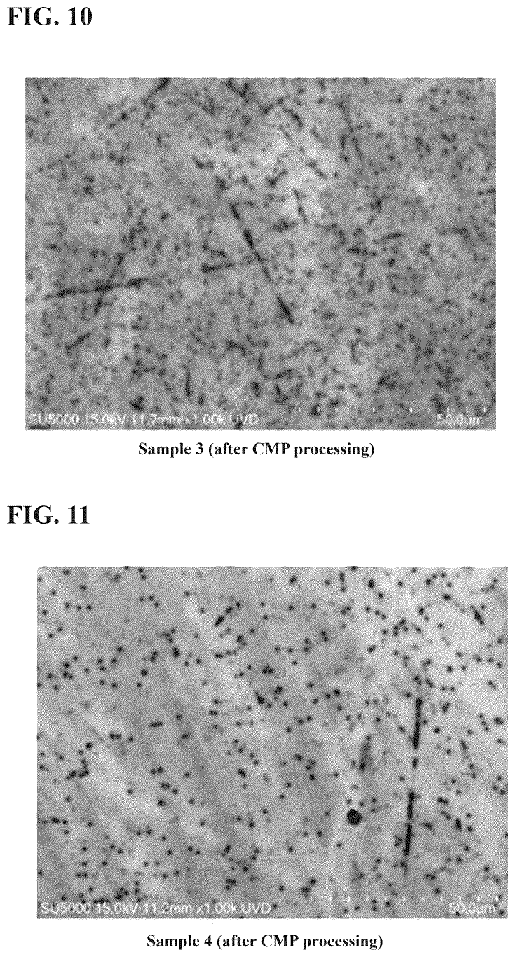

For Samples 1 to 4 after CMP processing, CL observation of the main surfaces of them was performed. FIG. 8 shows a CL image of the main surface (after CMP processing) of Sample 1, FIG. 9 shows a CL image of the main surface (after CMP processing) of Sample 2, FIG. 10 shows a CL image of the main surface (after CMP processing) of Sample 3, and FIG. 11 shows a CL image of the main surface (after CMP processing) of Sample 4. As shown in FIG. 8, no dark areas or dark lines are present in the main surface of Sample 1, which was subjected to CMP processing while controlling the contact area between the main surface of the workpiece and the CMP pad to be smaller than the area of the main surface. On the other hand, as shown in FIGS. 9 to 11, dark areas and dark lines were present in the main surfaces of Samples 2 to 4 that had been subjected to CMP processing using the conventional configuration, and the processing-affected layer was not completely removed. The dark spots observed in FIGS. 8 to 11 are non-light-emitting areas corresponding to threading dislocations. The more the processing-affected layer, that is, the more the dark lines and dark areas, the more difficult it becomes to obtain a contrast between the dark spots and the light-emitting areas in the CL image. Therefore, even in the crystal with similar threading dislocation densities, no dark spots are observed in FIG. 7 before CMP processing. It can be said that there is a correlation between the contrast between the dark spots and the light-emitting areas in FIGS. 8 to 11, that is, between the ease of observing the dark spots, and the light diffusion transmittance of the present disclosure, which will be described later.

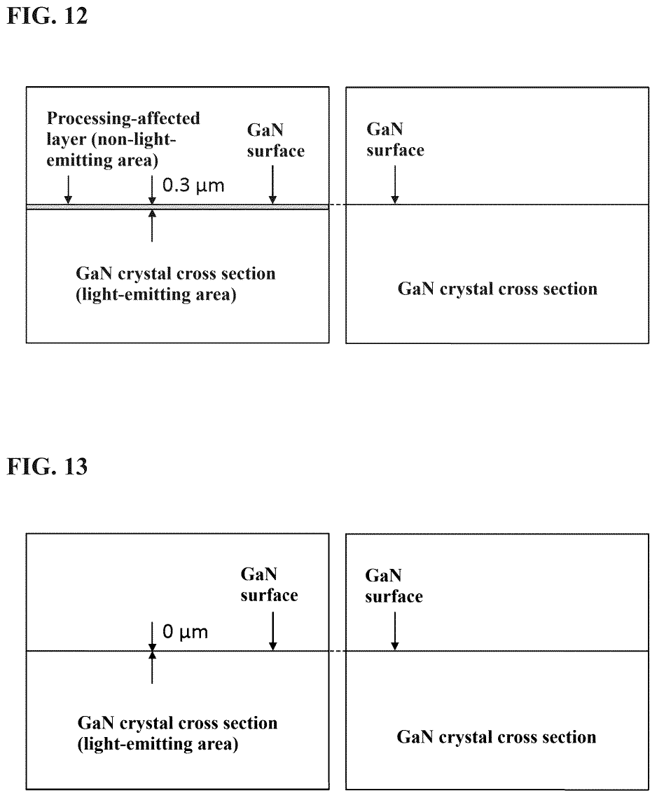

Further, for Sample 1, CL observation and SEM observation were performed to the cross section before and after CMP processing in the same field of view. However, the cross-sectional sample before CMP processing was a different sample that had been subjected to pre-CMP processing (precision grinding) similar to Sample 1, and it was confirmed in advance that the processing-affected layer after this pre-CMP processing was likely to be generated. FIG. 12 is a view showing a CL image (left side of the page) and an SEM image (right side of the page) of another sample similar to Sample 1 before CMP processing, and FIG. 13 is a view showing a CL image (left side of the page) and an SEM image (right side of the page) of Sample 1 after CMP processing. The SEM image shows a physical boundary region, and the CL image shows a boundary region between the light-emitting region without processing-affected crystal defects and the non-light-emitting region (processing-affected layer) with processing-affected crystal defects. Therefore, the difference in the boundary region between the CL image and the SEM image indicates the thickness of the processing-affected layer. As shown in FIG. 12, in another sample similar to Sample 1 before CMP processing, the difference in the boundary regions of the CL image and the SEM image was 0.3 μm. In contrast, as shown in FIG. 13, in Sample 1 after CMP processing, the boundary regions of the CL image and the SEM image were same. From the results of the surface CL observation and the cross-sectional CL observation, it can be said that the processing-affected layer was completely removed in Sample 1 after CMP processing.

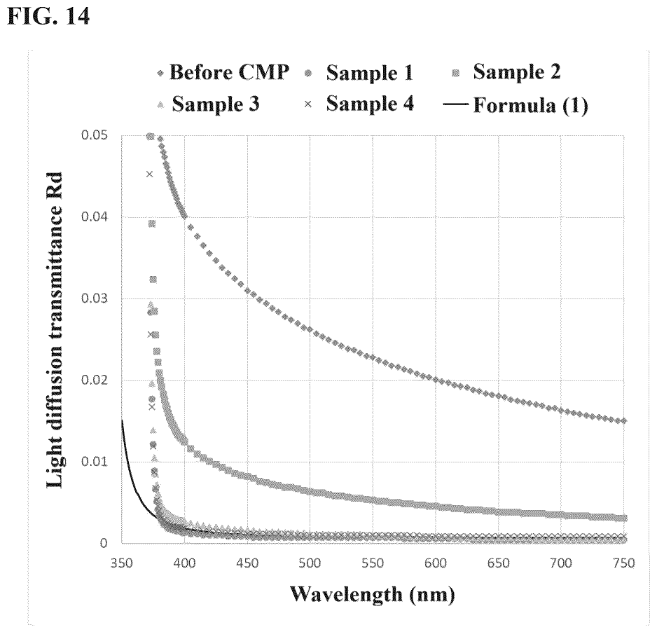

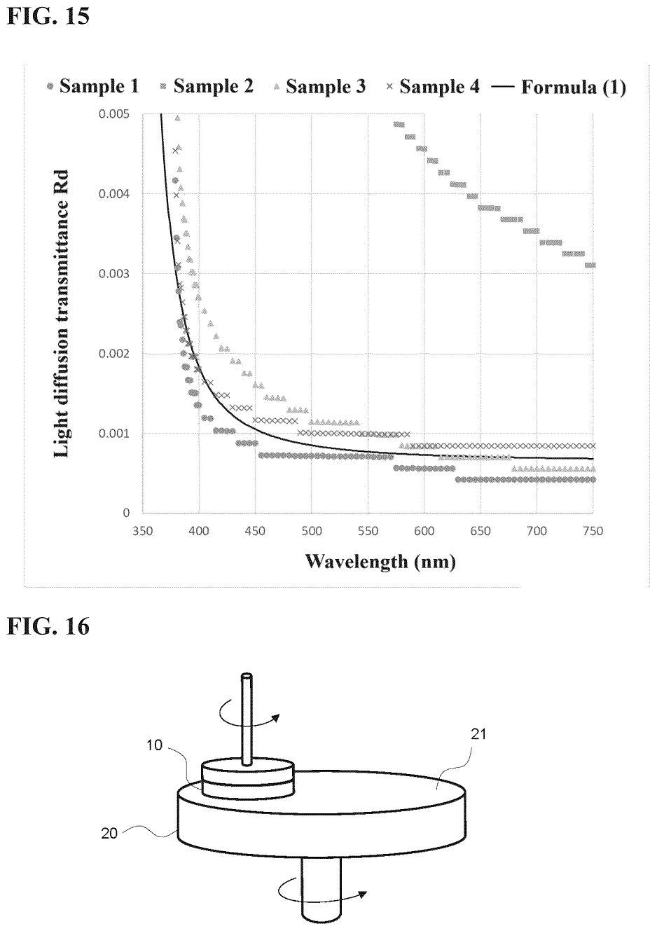

For Sample 1 before CMP processing and Samples 1 to 4 after CMP processing, the light diffusion transmittance Rd was calculated using a spectrophotometer, and the processing-affected layer was evaluated. The spectrophotometer used was an ultraviolet-visible-near infrared spectrophotometer (UH4150) manufactured by Hitachi High-Tech Corporation. Measurement wavelengths were 200 to 2500 nm, scanning was performed from a long wavelength to a short wavelength, a scanning speed was 600 nm/min, and a sampling interval was 1 nm. FIGS. 14 and 15 show the results. FIGS. 14 and 15 also show graphs showing the right side of the following formula (1).

$$Rd < a \times {b}^{2} \div ( c \times {( λ - λ0 )}^{2} + {b}^{2} ) + d \qquad ( 1 )$$

In the formula (1), a=10, b=1.2, c=2.5, d=0.00065, λ is the wavelength (nm) of the incident light, and λ₀=330.

FIGS. 14 and 15 show the light diffusion transmittance Rd at the wavelengths of 350 to 750 nm out of the measured wavelengths. In FIG. 14, the vertical axis is adjusted so as to show the wavelength dependency of the light diffusion transmittance Rd of Sample 1 before CMP processing. Although FIG. 15 does not show the light diffusion transmittance Rd of Sample 1 before CMP processing, the vertical axis is adjusted so as to show the difference between Samples 1 to 4 after CMP processing. As shown in FIG. 15, in Sample 1 which was subjected to CMP processing while controlling the contact area between the main surface of the workpiece and the CMP pad to be smaller than the area of the main surface, the light diffusion transmittance Rd satisfied the above formula (1) at the wavelength λ of the incident light over an entire range of 390 nm or more and 600 nm or less. On the other hand, in Samples 2 to 4, which were subjected to CMP processing using a conventional configuration, the light diffusion transmittance Rd did not satisfy the above formula (1) at the wavelength λ of the incident light over the entire (or most) range of 390 nm or more and 600 nm or less. Further, Sample 1 was the only sample in which the light diffusion transmittance Rd of the light having a wavelength of 532 nm, satisfied the above formula (1).

As described above, it was confirmed that the processing-affected layer can be completely removed by performing CMP processing while controlling the contact area between the main surface of the workpiece and the CMP pad so that it is smaller than the area of the main surface. It was also confirmed that the processing-affected layer of the GaN substrate can be accurately evaluated by calculating the light diffusion transmittance Rd using a spectrophotometer. This method of evaluating the processing-affected layer using the diffusion light transmittance is non-destructive and does not involve contact with the processed main surface of the workpiece. Therefore, the processing-affected layer can be evaluated with no influence of surface deposits that occur in the case of the scattering evaluation using laser light, as in the conventional art described above, or with no problems such as surface damage and carbon deposits that result from electron beam irradiation by cathodoluminescence.

### Example 2

First, two workpieces composed of gallium nitride single crystal having a diameter of 100 mm and a threading dislocation density of 3×10⁶ cm⁻² in the c-plane were prepared as samples 5 and 6. Samples 5 and 6 were subjected to precision grinding so that the surface roughness Ra of both main surfaces was 10 nm or less.

Next, for Samples 5 and 6, CMP processing was performed to the main surfaces of both until the surface roughness Ra of the main surfaces became 1 nm or less. For Sample 5, CMP processing was performed using the configuration shown in FIG. 2, which was explained as the first embodiment, and the contact area between the main surface of the workpiece and the CMP pad was controlled to be 20% of the area of the main surface. For Sample 6, CMP processing was performed using the configuration shown in FIG. 16, which was explained as a conventional example.

For Samples 5 and 6 after CMP processing, the light diffusion transmittance Rd was calculated using a spectrophotometer to evaluate the processing-affected layer. The light diffusion transmittance Rd was measured at five points in plan view: the substrate center (measurement point a), 20 mm right side position from the substrate center (measurement point b), 20 mm left side position from the substrate center (measurement point c), 20 mm upper side position from the substrate center (measurement point d), and 20 mm lower side position from the substrate center (measurement point e). Table 1 shows the light diffusion transmittance Rd at each measurement point when the wavelength λ of the incident light is 532 nm.

TABLE 1

| | | Light diffusion transmittance Rd |
|---|---|---|
| | | (λ = 532 nm) |
| Sample 5 | a | 7.11E−04 |
| | b | 7.22E−04 |
| | c | 7.07E−04 |
| | d | 7.27E−04 |
| | e | 6.99E−04 |
| | Average | 7.13E−04 |
| | Deviation | 3.93% |
| Sample 6 | a | 1.146−03 |
| | b | 1.16E−03 |
| | c | 1.08E−03 |
| | d | 1.19E−03 |
| | e | 1.09E−03 |
| | Average | 1.13E−03 |
| | Deviation | 9.72% |

As shown in Table 1, in Sample 5, which was subjected to CMP processing while controlling the contact area between the main surface of the workpiece and the CMP pad to 20% of the area of the main surface, deviation of the light diffusion transmittance Rd ((maximum value−minimum value)÷average value) was 5% or less. On the other hand, in Sample 6, which was subjected to CMP processing using the conventional configuration, the deviation of the light diffusion transmittance Rd ((maximum value−minimum value)/average value) exceeded 5%. Further, the right side of formula (1) is 7.91×10⁻⁴ at the wavelength of λ=532 nm, and it is found that the large/small relationship of the light diffusion transmittance Rd is as follows: Sample 5<formula (1)<Sample 6.

As described above, it was confirmed that by appropriately controlling the contact area between the main surface of the workpiece and the CMP pad during CMP processing, the deviation of the light diffusion transmittance Rd ((maximum value−minimum value)÷average value) could be reduced to 5% or less. This indicates that the processing-affected layer is removed uniformly over the surface.

<Preferable aspects of the present disclosure>

Preferable aspects of the present disclosure will be described below.

### (Supplementary Description 1)

A gallium nitride single crystal substrate,
that is a gallium nitride single crystal substrate having a diameter of 50 mm or more and two main surfaces facing in opposite directions,
wherein when light having a wavelength of 532 nm is incident perpendicularly to one of the main surfaces, light diffusion transmittance Rd, which is a value obtained by dividing an intensity of diffused transmitted light by an intensity of total transmitted light, satisfies Rd<0.000791.

### (Supplementary Description 2)

There is provided a gallium nitride single crystal substrate,
that is a gallium nitride single crystal substrate having a diameter of 50 mm or more and two main surfaces facing in opposite directions,
wherein when light is incident perpendicularly to one of the main surfaces using a spectrophotometer, at least one wavelength λ of incident light is in a range of 390 nm or more and 600 nm or less, at which light diffusion transmittance Rd, which is a value obtained by dividing an intensity of diffused transmitted light by an intensity of total transmitted light, satisfies the following formula (1):

$$Rd < a \times {b}^{2} \div ( c \times {( λ - {λ}_{0} )}^{2} + {b}^{2} ) + d \qquad ( 1 )$$

[In formula (1), a=10, b=1.2, c=2.5, d=0.00065, λ is a wavelength (nm) of the incident light, and λ₀=330.]

### (Supplementary Description 3)

There is provided the gallium nitride single crystal substrate according to supplementary description 2,
wherein, when the wavelength λ (nm) of the incident light is an integer value, the light diffusion transmittance Rd satisfies the formula (1) at a wavelength value of λ equal to or greater than half of the range of 390 nm or more and 600 nm or less.

### (Supplementary Description 4)

There is provided the gallium nitride single crystal substrate according to supplementary description 2,
wherein the light diffusion transmittance Rd satisfies the formula (1) at the wavelength λ of the incident light over an entire range of 390 nm or more and 600 nm or less.

### (Supplementary Description 5)

There is provided the gallium nitride single crystal substrate according to supplementary description 1 or 2,
wherein a deviation ((maximum value−minimum value)÷average value) when the light diffusion transmittance Rd is measured at multiple arbitrary points on the main surface is 5% or less.

### (Supplementary Description 6)

There is provided a gallium nitride single crystal substrate manufacturing method including:
preparing a gallium nitride single crystal intermediate having a main surface with a surface roughness Ra of 10 nm or less and a processing-affected layer present thereon; and
performing chemical mechanical polishing to the main surface,
wherein in the performing the chemical mechanical polishing, a contact area between the main surface and a polishing pad is set to be smaller than an area of the main surface.

Preferably, a contact area S_{c} is controlled in accordance with a threading dislocation density TDD in the main surface.

Preferably, the contact area S_{c} is set to 10% or less of the area S₀ of the main surface when the threading dislocation density TDD is 1×10⁷ cm⁻² or more, and is set to more than 10% and 30% or less of S₀ when TDD is 1×10⁶ cm⁻² or more and less than 1×10⁷ cm⁻², and is set to be more than 30% and 50% or less of S₀ when TDD is 1×10⁵ cm⁻² or more and less than 1×10⁶ cm⁻², and is set to more than 50% and less than 100% of S₀ when TDD is less than 1×10⁵ cm⁻².

### (Supplementary Description 7)

There is provided a gallium nitride single crystal substrate evaluation method in which when light having a wavelength of 532 nm is incident perpendicularly to a main surface of a gallium nitride single crystal substrate, presence or absence of a processing-affected layer is evaluated based on whether a light diffusion transmittance Rd, which is a value obtained by dividing an intensity of diffused transmitted light by an intensity of total transmitted light, satisfies Rd<0.000791.

Preferably, the presence or absence of the processing-affected layer is evaluated based on whether or not there is at least one wavelength λ of incident light in a range of 390 nm or more and 600 nm or less at which a light diffusion transmittance Rd satisfies the following formula (1):

$$Rd < a \times {b}^{2} \div ( c \times {( λ - {λ}_{0} )}^{2} + {b}^{2} ) + d \qquad ( 1 )$$

[In the formula (1), a=10, b=1.2, c=2.5, d=0.00065, λ is a wavelength (nm) of the incident light, and λ₀=330.]

Preferably, when the wavelength λ (nm) of the incident light is an integer value, the presence or absence of the processing-affected layer is evaluated based on whether or not the light diffusion transmittance Rd satisfies the formula (1) at a wavelength value of λ of half or more of a range of 390 nm or more and 600 nm or less.

Preferably, the presence or absence of the processing-affected layer is evaluated based on whether or not the light diffusion transmittance Rd satisfies the formula (1) at a wavelength λ of the incident light over an entire range of 390 nm or more and 600 nm or less.

### (Supplementary Description 8)

A gallium nitride single crystal substrate having a diameter of 50 mm or more and two main surfaces facing in opposite directions,
wherein CL observation of a cross section obtained by cleaving the gallium nitride single crystal substrate, reveals that no dark areas corresponding to the processing-affected layer are observed in a region up to 150 nm from the main surface.

What is claimed is:

1. A gallium nitride single crystal substrate,
that is a gallium nitride single crystal substrate having a diameter of 50 mm or more and two main surfaces facing in opposite directions,
wherein when light having a wavelength of 532 nm is incident perpendicularly to one of the main surfaces, light diffusion transmittance Rd, which is a value obtained by dividing an intensity of diffused transmitted light by an intensity of total transmitted light, satisfies Rd<0.000791.

2. A gallium nitride single crystal substrate,
that is a gallium nitride single crystal substrate having a diameter of 50 mm or more and two main surfaces facing in opposite directions,
wherein when light is incident perpendicularly to one of the main surfaces using a spectrophotometer, at least one wavelength λ of incident light is in a range of 390 nm or more and 600 nm or less, at which light diffusion transmittance Rd, which is a value obtained by dividing an intensity of diffused transmitted light by an intensity of total transmitted light, satisfies the following formula (1):
$$Rd < a \times {b}^{2} \div ( c \times {( λ - {λ}_{0} )}^{2} + {b}^{2} ) + d \qquad ( 1 )$$
[In formula (1), a=10, b=1.2, c=2.5, d=0.00065, λ is a wavelength (nm) of the incident light, and λ₀=330.]

3. The gallium nitride single crystal substrate according to claim 2, wherein the light diffusion transmittance Rd satisfies the formula (1) at the wavelength λ of the incident light over an entire range of 390 nm or more and 600 nm or less.

4. The gallium nitride single crystal substrate according to claim 1, wherein a deviation ((maximum value−minimum value)÷average value) when the light diffusion transmittance Rd is measured at multiple arbitrary points on the main surface is 5% or less.

5. The gallium nitride single crystal substrate according to claim 2, wherein a deviation ((maximum value−minimum value)÷average value) when the light diffusion transmittance Rd is measured at multiple arbitrary points on the main surface is 5% or less.
